(19) United States
(12) Patent Application Publication
(10) Pub. No.: US 2026/0254192 A1
(43) Pub. Date: Aug. 27, 2026

(54) HEADER FOR SEMICONDUCTOR PACKAGE

(71) Applicant: SHINKO ELECTRIC INDUSTRIES CO., LTD., Nagano (JP)

(72) Inventors: Takaharu MIYAMOTO, Nagano (JP); Akihisa WATANABE, Nagano (JP)

(21) Appl. No.: 19/543,369

(22) Filed: Feb. 18, 2026

(30) Foreign Application Priority Data
Feb. 26, 2025 (JP) 2025-029316

(51) Int. Cl. H01S 5/02212; H01S 5/02218

(52) U.S. Cl. CPC H01S 5/02212; H01S 5/02218

(57) ABSTRACT

A header for a semiconductor package includes a first eyelet provided with a first through hole, a second eyelet bonded on the first eyelet and provided with a second through hole communicating with the first through hole, a lead inserted into the first through hole and the second through hole, and a sealing material that seals the lead inside the first through hole. An opening area of the second through hole is smaller than an opening area of the first through hole in a plan view, and a dielectric constant in a periphery of the lead inside the second through hole is smaller than a dielectric constant of the sealing material.

### CROSS-REFERENCE TO RELATED APPLICATIONS

This application is based upon and claims priority to Japanese Patent Application No. 2025-029316, filed on Feb. 26, 2025, the entire contents of which are incorporated herein by reference.

### FIELD

Certain aspects of the embodiments discussed herein are related to headers for semiconductor packages.

### BACKGROUND

A known header for a semiconductor package for mounting a semiconductor device has a structure including a circular eyelet and a sealing material. For example, the eyelet has a first hole with a large diameter provided on a lower surface side of the eyelet, and a second hole with a small diameter provided on an upper surface side of the eyelet. A lead is inserted through the first hole and the second hole, and the sealing material is provided inside the first hole to seal the lead.

Examples of related art include Japanese Laid-Open Patent Publication No. H06-29451, for example.

In the header for the semiconductor package described above, it is difficult to control a thickness of the sealing material located inside the first hole of the eyelet to a designed value. A variation in the thickness of the sealing material affects a characteristic impedance of the lead.

### SUMMARY

It is an object in one aspect of the embodiments of the present disclosure to provide a header for a semiconductor package capable of reducing a thickness variation of a sealing material that seals a lead.

According to one aspect of the embodiments of the present disclosure, a header for a semiconductor package, includes a first eyelet provided with a first through hole; a second eyelet bonded on the first eyelet and provided with a second through hole communicating with the first through hole; a lead inserted into the first through hole and the second through hole; and a sealing material that seals the lead inside the first through hole, wherein an opening area of the second through hole is smaller than an opening area of the first through hole in a plan view, and a dielectric constant in a periphery of the lead inside the second through hole is smaller than a dielectric constant of the sealing material.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIGS. 1A and 1B are diagrams illustrating an example of a header for a semiconductor package according to a first embodiment;

FIGS. 2A and 2B are cross sectional views illustrating the example of the header for the semiconductor package according to the first embodiment;

FIG. 3 is a cross sectional view illustrating a state where a cap is attached to the header for the semiconductor package according to the first embodiment;

FIG. 4 is a cross sectional view illustrating an example of the header for the semiconductor package according to a first modification of the first embodiment;

FIG. 5 is a cross sectional view illustrating an example of the header for the semiconductor package according to a second modification of the first embodiment;

FIGS. 6A and 6B are diagrams illustrating an example of the header for the semiconductor package according to a second embodiment;

FIGS. 7A and 7B are cross sectional views illustrating the example of the header for the semiconductor package according to the second embodiment;

FIGS. 8A and 8B are cross sectional views illustrating an example of the header for the semiconductor package according to a modification of the second embodiment; and

FIG. 9 is a cross sectional view illustrating a state where the cap is attached to the header for the semiconductor package according to the modification of the second embodiment.

### DESCRIPTION OF EMBODIMENTS

Hereinafter, embodiments of the present invention will be described with reference to the drawings. In the drawings, the same components or constituent elements are designated by the same reference numerals, and a redundant description thereof may be omitted.

### First Embodiment

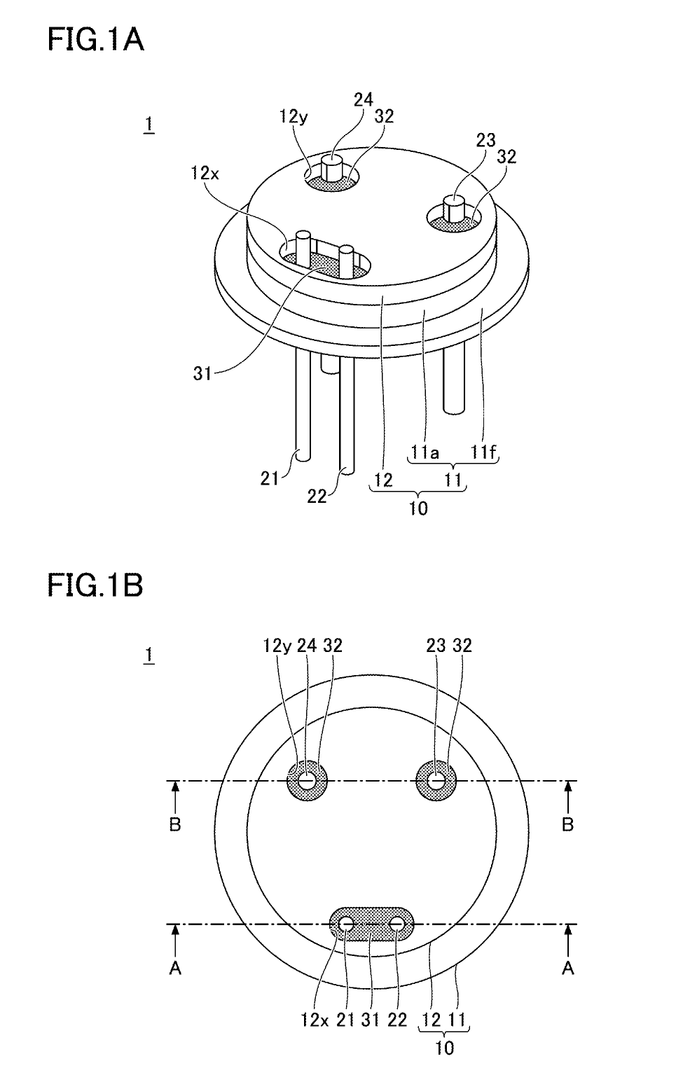

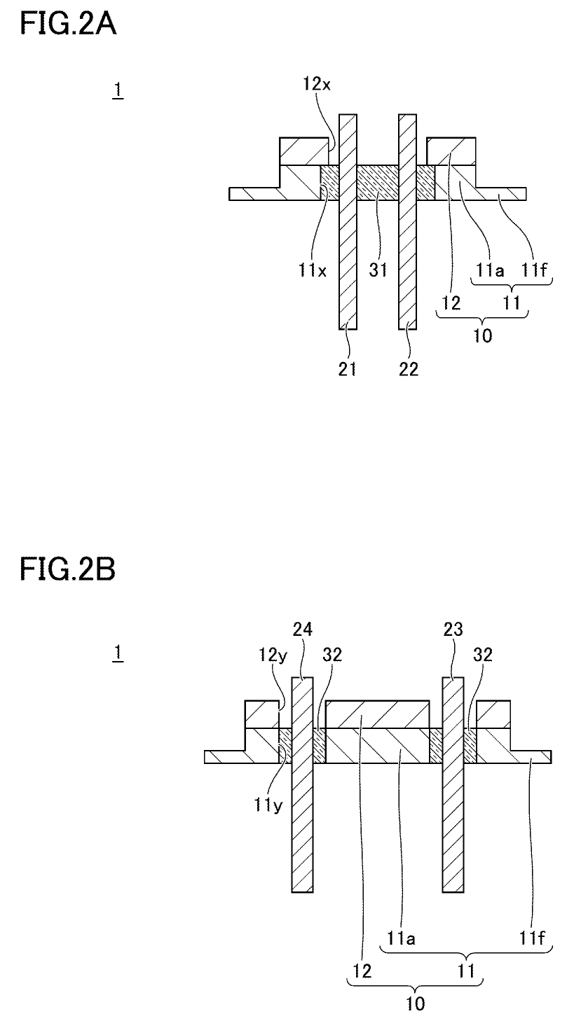

FIG. 1A and FIG. 1B are diagrams illustrating an example of a header for a semiconductor package according to a first embodiment. FIG. 1A is a perspective view of the header, and FIG. 1B is a plan view of the header. FIG. 2A and FIG. 2B are cross sectional views illustrating the example of the header for the semiconductor package according to the first embodiment. FIG. 2A illustrates a cross section of the header taken along a line A-A in FIG. 1B, and FIG. 2B illustrates a cross section of the header taken along a line B-B in FIG. 1B.

As illustrated in FIG. 1A, FIG. 1B, FIG. 2A, and FIG. 2B, a header 1 for a semiconductor package includes an eyelet 10, a lead 21, a lead 22, a lead 23, a lead 24, and sealing materials (or sealing members) 31 and 32. The header 1 can be used as a header of a laser for optical communication, for example.

When it is not necessary to distinguish the lead 21, the lead 22, the lead 23, and the lead 24 from one another, the leads 21 through 24 are simply referred to as "leads".

The eyelet 10 includes a first eyelet 11, and a second eyelet 12 bonded on the first eyelet 11. The first eyelet 11 can be made of iron, Kovar, or a nickel-iron alloy, for example. A material constituting the second eyelet 12 may be the same as the material constituting the first eyelet 11, or may be a material having high thermal conductivity, such as copper or the like.

The first eyelet 11 includes a main body 11a and a flange 11f, for example. The main body 11a has a disk shape, for example. A diameter of the main body 11a is not particularly limited, and can be appropriately determined depending on the purpose. For example, the diameter of the main body 11a may be 3.8 mm, 5.6 mm, 9.0 mm, or the like.

In the present specification, a member having the disk shape refers to a member having a substantially circular planar shape and a predetermined thickness. The thickness of the member may be larger than or smaller than the diameter of the member. Further, the member having the disk shape may partially include a recess, a protrusion, a through hole, or the like. In the present specification, a plan view refers to a view of an object in a normal direction to an upper surface of the eyelet 10, and a planar shape refers to a shape of the object in the plan view viewed in the normal direction to the upper surface of the eyelet 10.

The flange 11f is a plate-shaped member that protrudes outward in an annular shape in the plan view from a lower end of a side surface of the main body 11a. The flange 11f has a ring shape, for example. The flange 11f may have a thickness of approximately 0.5 mm to approximately 0.8 mm, for example. The flange 11f can be formed integrally with the main body 11a, for example. The main body 11a may not include the flange 11f.

The main body 11a is provided with through holes 11x and 11y penetrating the main body 11a from an upper surface to a lower surface of the main body 11a. In the illustrated example, one through hole 11x having an elongated shape in the plan view, and two through holes 11y having a circular shape in the plan view, are provided in the main body 11a.

The second eyelet 12 has a disk shape, for example. A lower surface of the second eyelet 12 is bonded to an upper surface of the first eyelet 11 using a metal brazing alloy (silver brazing alloy, gold-tin alloy, or the like) or a conductive adhesive, for example. The upper surface of the first eyelet 11 refers to the upper surface of the main body 11a. A diameter of the lower surface of the second eyelet 12 may be the same as a diameter of the upper surface of the first eyelet 11. A diameter of the lower surface of second eyelet 12 may be smaller than the diameter of the upper surface of first eyelet 11.

The second eyelet 12 is provided with through holes 12x and 12y penetrating the second eyelet 12 from the upper surface to the lower surface of the second eyelet 12. In the illustrated example, one through hole 12x having an elongated shape in the plan view, and two through holes 12y having a circular shape in the plan view, are provided in the second eyelet 12. The through hole 12x communicates with the through hole 11x, and the through hole 12y communicates with the through hole 11y. In the plan view, an opening area of the through hole 12x may be smaller than an opening area of the through hole 11x. In the plan view, an opening area of the through hole 12y may be the same as an opening area of the through hole 11y. In this example, the opening areas of the through holes 11x and 11y are defined at a position of a plane including the upper surface of the first eyelet 11. The opening areas of the through holes 12x and 12y are defined at a position of a plane including the upper surface of the second eyelet 12.

A thickness of the eyelet 10 may be approximately 0.4 mm to approximately 2 mm, for example. The thickness of the eyelet 10 is preferably 0.8 mm or greater, and a thickness of the main body 11a of the first eyelet 11 is preferably 0.45 mm or greater. By setting the thickness of the main body 11a to 0.45 mm or greater, it becomes easy to secure airtightness when the sealing material 31 is provided inside the through hole 11x. A thickness of the flange 11f may be 0.2 mm to 0.3 mm, for example.

The leads 21 and 22 are inserted into the through holes 11x and 12x with the longitudinal direction thereof directed in a thickness direction of the eyelet 10. The leads 21 and 22 are sealed by the sealing material 31 in peripheries of the leads 21 and 22 inside the through hole 11x. On the other hand, the leads 21 and 22 are not sealed by the sealing material 31 in the peripheries of the leads 21 and 22 inside the through hole 12x. In the through hole 12x, the leads 21 and 22 are surrounded by air. A thickness of the sealing material 31 is the same as the thickness of the first eyelet 11, for example. An upper surface of the sealing material 31 and the upper surface of the first eyelet 11 lie on a single plane (that is, lie on the same plane), for example. A lower surface of the sealing material 31 and the lower surface of the first eyelet 11 lie on a single plane, for example.

The leads 23 and 24 are inserted into the through holes 11y and 12y with the longitudinal direction thereof directed in the thickness direction of the eyelet 10. The leads 23 and 24 are sealed by the sealing material 32 in peripheries of the leads 23 and 24 inside the through hole 11y. On the other hand, the leads 23 and 24 are not sealed by the sealing material 32 in the peripheries of the leads 23 and 24 inside the through hole 12y. In the through hole 12y, the leads 23 and 24 are surrounded by air. A thickness of the sealing material 32 is the same as the thickness of the first eyelet 11, for example. An upper surface of the sealing material 32 and the upper surface of the first eyelet 11 lie on a single plane, for example. A lower surface of the sealing material 32 and the lower surface of the first eyelet 11 lie on a single plane, for example.

Each of the leads 21 through 24 protrudes upward from the upper surface of the eyelet 10. An amount of lead protrusion from the upper surface of the eyelet 10 is approximately 0.1 mm to approximately 0.3 mm, for example. Each of the leads 21 through 24 protrudes downward from the lower surface of the eyelet 10. An amount of lead protrusion from the lower surface of the eyelet 10 is approximately 6 mm to approximately 10 mm, for example. Each of the leads 21 through 24 is made of a metal, such as an iron-nickel alloy, Kovar, or the like, and gold plating or the like may be formed on a surface of each of the leads 21 through 24.

The leads 21 and 22 are arranged adjacent to each other, and serve as a path which is electrically connected to a light emitting element and through which a signal passes when the light emitting element is mounted on the header 1 and used as the semiconductor package. The leads 23 and 24 serve as a path which is electrically connected to a power supply, and a device, a sensor, or the like mounted on the header 1 and through which the signal passes. The device, the sensor, or the like mounted on the header 1 is a Peltier device or a temperature sensor, for example. The number of leads 21 through 24 is not particularly limited, and may be increased or decreased as necessary.

A diameter of the leads 21 through 24 (wire diameter) is approximately 0.2 mm or greater and approximately 0.6 mm or less, for example. As described above, the leads 21 and 22 serve as the path which is electrically connected to the light emitting element and through which the signal passes when the light emitting element is mounted on the header 1 and used as the semiconductor package. For this reason, the leads 21 and 22 preferably have a wire diameter that is as small as possible to increase the impedance. When a strength and the impedance are taken into consideration, the wire diameter of the leads 21 and 22 is preferably 0.2 mm or greater and 0.25 mm or less.

On the other hand, the wire diameter of the leads 23 and 24 used for the power supply or the like is preferably made large to a certain extent to reduce the impedance. Specifically, the wire diameter of the leads 23 and 24 is preferably 0.3 mm or greater and 0.6 mm or less when a product size is also taken into consideration. As described above, in the header 1, the wire diameter of the leads 21 and 22 serving as the path which is electrically connected to the light emitting element and through which the signal passes when the light emitting element is mounted on the header 1 and used as the semiconductor package is preferably smaller than the wire diameter of the other leads 23 and 24 used for the power supply or the like.

The sealing materials 31 and 32 are made of an insulating material, such as glass or the like, for example. The material used for the sealing material 31 and the material used for the sealing material 32 may be the same or different. In a case where glass is used for the sealing material 31, a dielectric constant of the glass is preferably 4 or greater and 7 or less, more preferably 4 or greater and 6 or less, and even more preferably 4 or greater and 5 or less. Examples of the glass having such a dielectric constant include glass including Na₂O, BaO, and SiO₂, and glass including Na₂O, Al₂O₃, B₂O₃, and SiO₂. In order to obtain good high-frequency characteristics, a loss tangent tanδ of the glass used for the sealing material 31 is preferably 5 × 10⁻⁴ or less.

In order to seal the leads 21 and 22 with the sealing material 31, first, the leads 21 and 22 and an uncured material that becomes the sealing material 31 are disposed inside the through hole 11x of the first eyelet 11. Then, the uncured material that becomes the sealing material 31 is sandwiched between flat plates or the like from above and below, and is cured to form the sealing material 31. Hence, the upper surface of the sealing material 31 and the upper surface of the first eyelet 11 can be made to lie on a single plane, and the lower surface of the sealing material 31 and the lower surface of the first eyelet 11 can be made to lie on a single plane. That is, it is possible to provide the header 1 for the semiconductor package, that can reduce variations in the thickness of the sealing material 31 that seals the leads 21 and 22.

In addition, it is not necessary to place glass having a high melting temperature above and below the sealing material 31 inside the header 1, or to perform a treatment that does not suit or is incompatible with the uncured material that becomes the sealing material 31 on an inner wall surface of the through hole 12x, in order to reduce the variations in the thickness of the sealing material 31. For this reason, it is possible to reduce the variations in the thickness of the sealing material 31 without increasing manufacturing cost or reducing yield.

Moreover, in the header 1, the sealing material 31 made of the insulating material, such as glass or the like, having a dielectric constant higher than that of air is disposed around in the peripheries of the leads 21 and 22 inside the through hole 11x. Further, the leads 21 and 22 are surrounded by air inside the through hole 12x. According to such a structure, when the opening area of the through hole 12x is made smaller than the opening area of the through hole 11x in the plan view, a predetermined characteristic impedance (for example, 50 Ω) can be achieved. In addition, because the opening area of the through hole 12x is smaller than the opening area of the through hole 11x, it is easy to secure the area of the upper surface of the second eyelet 12 while achieving the predetermined characteristic impedance, and a semiconductor device or the like can be disposed on the eyelet 10 with ease.

The peripheries of the leads 21 and 22 inside the through hole 12x may be other than air, as long as the dielectric constant in the peripheries of the leads 21 and 22 inside the through hole 12x is smaller than the dielectric constant of the sealing material 31. For example, a resin material having a dielectric constant lower than that of the sealing material 31 may be disposed in the peripheries of the leads 21 and 22 inside the through hole 12x. In this case, the leads 21 and 22 can be more firmly fixed with respect to the eyelet 10.

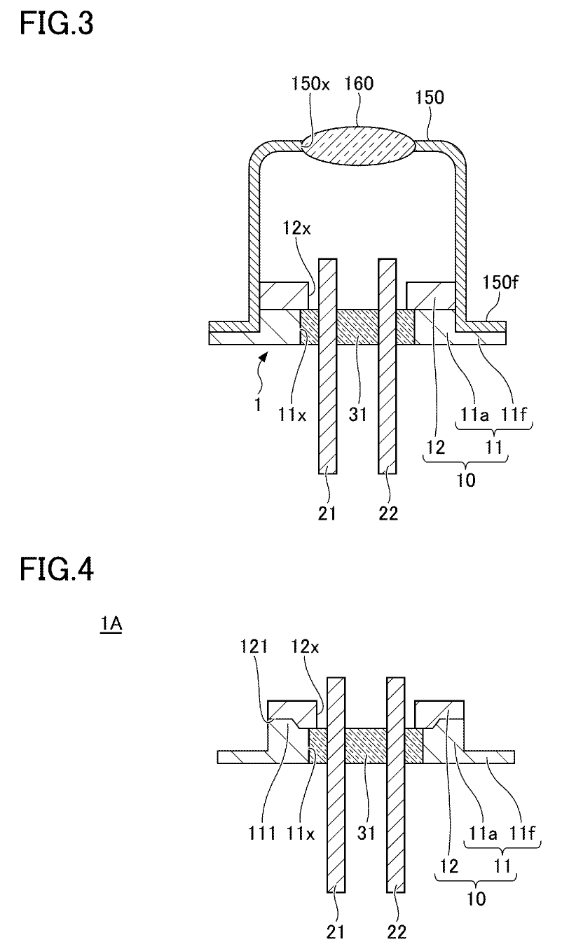

FIG. 3 is a cross sectional view illustrating a state where a cap is attached to the header for the semiconductor package according to the first embodiment. As illustrated in FIG. 3, the header 1 can be used by mounting a semiconductor device or the like on the eyelet 10 and then attaching a cap 150 to the eyelet 10.

The cap 150 is formed of a metal, such as iron, iron-nickel alloys, Kovar, or the like, and has an opening 150x at a substantially central portion of the cap 150 in the plan view. A transparent member 160 is formed of glass or the like, for example, and is fixed to the cap 150 by low-melting-point glass, an adhesive, or the like so as to close the opening 150x. The cap 150 includes a flange 150f that protrudes outward in an annular shape from a lower end of a side surface of the cap 150 in the plan view.

The cap 150 having the transparent member 160 fixed thereon is disposed so that the flange 150f is located on the flange 11f of the first eyelet 11, and can be bonded to the eyelet 10 by resistance welding or the like. Thus, the eyelet 10 and the cap 150 having the transparent member 160 fixed thereon can form an air-tightly sealed space.

### Modifications of First Embodiment

As modifications of the first embodiment, an example of the header for the semiconductor package in which the shapes of the first eyelet and the second eyelet are different from those of the first embodiment will be described. In the modifications of the first embodiment, a description of the same components or constituent elements as those of the first embodiment described above may be omitted.

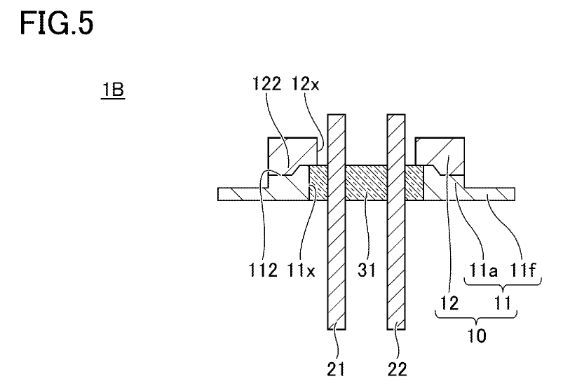

FIG. 4 is a cross sectional view illustrating an example of the header for the semiconductor package according to a first modification of the first embodiment. A header 1A illustrated in FIG. 4 differs from the header 1 in that the first eyelet 11 and the second eyelet 12 form a concavo-convex structure such that the first eyelet 11 and the second eyelet 12 are fitted to each other.

In the header 1A, a protrusion 111 protruding from the upper surface of the sealing material 31 is provided on the upper surface of the first eyelet 11. In addition, a recess 121 is provided in the lower surface of the second eyelet 12. The protrusion 111 of the first eyelet 11 is fitted into the recess 121 of the second eyelet 12.

The protrusion 111 and the recess 121 can be provided on the outer peripheral side of the eyelet 10 in the plan view, for example. The protrusion 111 and the recess 121 can be provided in an annular shape on the outer peripheral side of the eyelet 10 in the plan view, for example. The protrusion 111 and the recess 121 may be provided in a portion of a region on the outer peripheral side of the eyelet 10 in the plan view, for example. In this case, the concavo-convex structure formed by the first eyelet 11 and the second eyelet 12 can serve to prevent the first eyelet 11 and the second eyelet 12 from rotating relative to each other.

The protrusion 111 and the recess 121 may be provided in an arbitrary region other than the outer peripheral side of the eyelet 10 in the plan view.

FIG. 5 is a cross sectional view illustrating an example of the header for the semiconductor package according to a second modification of the first embodiment. A header 1B illustrated in FIG. 5 differs from the header 1A illustrated in FIG. 4 in the concavo-convex structure formed by the first eyelet 11 and the second eyelet 12 is different from that of the header 1A.

In the header 1B, a recess 112 recessed from the upper surface of the sealing material 31 is provided on the upper surface of the first eyelet 11. A protrusion 122 is provided on the lower surface of the second eyelet 12. The recess 112 of the first eyelet 11 is fitted over the protrusion 122 of the second eyelet 12.

The recess 112 and the protrusion 122 may be provided on the outer peripheral side of the eyelet 10 in the plan view, for example. The recess 112 and the protrusion 122 may be provided in an annular shape on the outer peripheral side of the eyelet 10 in the plan view, for example. The recess 112 and the protrusion 122 may be provided in a portion of the region on the outer peripheral side of the eyelet 10 in the plan view, for example. In this case, the concavo-convex structure formed by the first eyelet 11 and the second eyelet 12 can serve to prevent the first eyelet 11 and the second eyelet 12 from rotating relative to each other.

The recess 112 and the protrusion 122 may be provided in an arbitrary region other than the outer peripheral side of the eyelet 10 in the plan view.

As illustrated in FIG. 4 and FIG. 5, the first eyelet 11 and the second eyelet 12 form the concave-convex structure in which the first eyelet 11 and the second eyelet 12 fit relative to each other, so that the second eyelet 12 can easily be aligned with the first eyelet 11 when the second eyelet 12 is bonded onto the first eyelet 11.

### Second Embodiment

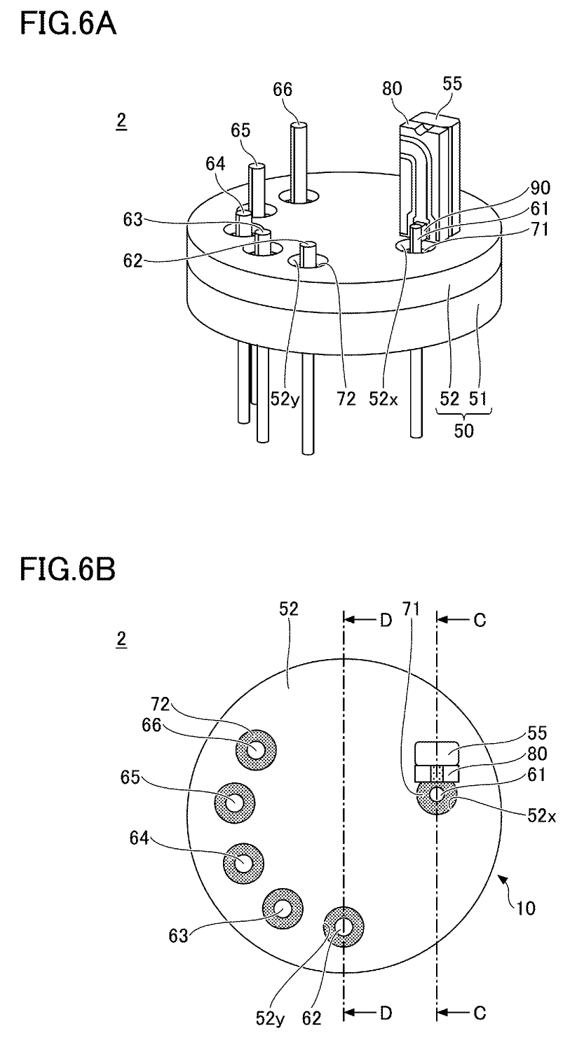

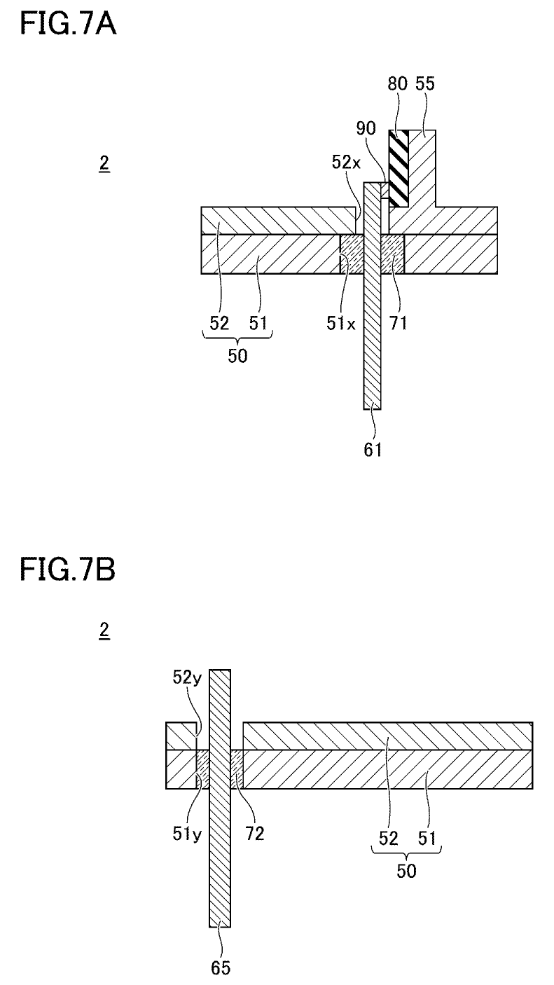

FIG. 6A and FIG. 6B are diagrams illustrating an example of the header for the semiconductor package according to a second embodiment. FIG. 6A is a perspective view of the header, and FIG. 6B is a plan view of the header. FIG. 7A and FIG. 7B are cross sectional views illustrating the example of the header for the semiconductor package according to the second embodiment. FIG. 7A illustrates a cross section of the header taken along a line C-C in FIG. 6B, and FIG. 7B illustrates a cross section of the header taken along a line D-D in FIG. 6B.

As illustrated in FIG. 6A, FIG. 6B, FIG. 7A, and FIG. 7B, a header 2 for a semiconductor package includes an eyelet 50, a lead 61, a lead 62, a lead 63, a lead 64, a lead 65, a lead 66, sealing materials 71 and 72, and a substrate 80. The header 2 can be used as a header of a laser for optical communication, for example. The substrate 80 may be provided as necessary.

The eyelet 50 includes a first eyelet 51 and a second eyelet 52 bonded on the first eyelet 51. A lower surface of the second eyelet 52 is bonded to an upper surface of the first eyelet 51 using a metal brazing alloy (silver brazing alloy, gold-tin alloy, or the like) or a conductive adhesive, for example. The material used for the first eyelet 51 and the second eyelet 52 can be selected from the examples of the material used for the first eyelet 11 and the second eyelet 12 described above, for example. Thicknesses of the first eyelet 51 and the second eyelet 52 may be the same as the thicknesses of the first eyelet 11 and the second eyelet 12, for example.

The first eyelet 51 and the second eyelet 52 have a disk shape, for example. A diameter of the first eyelet 51 is the same as the diameter of the second eyelet 52, for example. The diameters of the first eyelet 51 and the second eyelet 52 are not particularly limited, and can be appropriately determined depending on the purpose. The diameters of the first eyelet 51 and the second eyelet 52 may be 3.8 mm, 5.6 mm, 9.0 mm, or the like, for example. Similar to the first eyelet 11, the first eyelet 51 may include a flange that protrudes outward in an annular shape from the lower end of the side surface of the first eyelet 51 in the plan view.

The first eyelet 51 is provided with a through hole 51x and a through hole 51y that penetrate from the upper surface to the lower surface of the first eyelet 51. In the illustrated example, one through hole 51x having a substantially semi-circular shape in the plan view and five through holes 51y having circular shapes in the plan view are provided in the first eyelet 51.

The second eyelet 52 is provided with a through hole 52x and a through hole 52y that penetrate from the upper surface to the lower surface of the second eyelet 52. In the illustrated example, one through hole 52x having a substantially semi-circular shape in the plan view and five through holes 52y having a circular shape in the plan view are provided in the second eyelet 52. The through hole 52x communicates with the through hole 51x, and the through holes 52y communicate with the through holes 51y. In the plan view, an opening area of the through hole 52x may be smaller than an opening area of the through hole 51x. In the plan view, an opening area of the through hole 52y may be the same as an opening area of the through hole 51y. In this example, the opening areas of the through holes 51x and 51y are defined at a position of a plane including the upper surface of the first eyelet 51. The opening areas of the through holes 52x and 52y are defined at a position of a plane including the upper surface of the second eyelet 52.

The second eyelet 52 is provided with a substrate mounting part 55. The substrate mounting part 55 is a columnar member protruding from the upper surface of second eyelet 52. A side surface of the substrate mounting part 55 facing the lead 61 constitutes a substrate fixing surface on which the substrate 80 is fixed. The substrate mounting part 55 has a rectangular parallelepiped shape, for example, but may have an arbitrary shape as long as the substrate 80 can be fixed to the substrate mounting part 55. The substrate mounting part 55 can be formed integrally with a portion of the second eyelet 52 excluding the substrate mounting part 55 by press working or the like. When a workability of the press working is taken into consideration, a thickness of the second eyelet 52 in the portion excluding the substrate mounting part 55 is preferably 0.8 mm or greater.

The substrate 80 is fixed to a substrate fixing surface of the substrate mounting part 55. Interconnects including signal patterns and ground patterns are provided on a surface of the substrate 80 (a surface facing the lead 61), for example. The ground pattern having a solid configuration is provided on a back surface (surface facing the substrate mounting part 55) of the substrate 80. The ground pattern on a front surface of the substrate 80 and the ground pattern on the back surface of the substrate 80 can be electrically connected to each other via a through hole penetrating the substrate 80.

The back surface of the substrate 80 is fixed to the substrate fixing surface of the substrate mounting part 55 by a conductive material, such as a metal brazing alloy (for example, a gold-tin alloy) or the like. As a result, the ground pattern on the back surface of the substrate 80 is electrically connected to the substrate mounting part 55, and the substrate mounting part 55 has a ground (GND) potential (reference potential).

The substrate 80 is made of ceramics, for example. Specifically, the substrate 80 is made of aluminum oxide (alumina) or aluminum nitride. The signal patterns and the ground patterns can be formed of tungsten, titanium, gold, or the like, for example. Gold plating or the like may be formed on the surfaces of the signal patterns and the ground patterns.

The lead 61 is inserted into the through holes 51x and 52x with the longitudinal direction thereof directed in a thickness direction of the eyelet 50. The lead 61 is sealed by the sealing material 71 at a periphery thereof inside the through hole 51x, and is not sealed by the sealing material 71 at the periphery thereof inside the through hole 52x. In the through hole 52x, the lead 61 is surrounded by air. A thickness of the sealing material 71 is the same as the thickness of the first eyelet 51, for example. An upper surface of the sealing material 71 and the upper surface of the first eyelet 51 lie on a single plane, for example. A lower surface of the sealing material 71 and the lower surface of the first eyelet 51 lie on a single plane, for example.

The leads 62 through 66 are inserted into the through holes 51y and 52y with the longitudinal direction thereof directed in the thickness direction of the eyelet 50. The leads 62 through 66 are sealed by the sealing material 72 at the peripheries thereof inside the through hole 51y, and are not sealed by the sealing material 72 at the peripheries thereof inside the through hole 52y. In the through holes 52y, the leads 62 through 66 are surrounded by air. A thickness of the sealing material 72 is the same as the thickness of the first eyelet 51, for example. An upper surface of the sealing material 72 and the upper surface of the first eyelet 51 lie on a single plane, for example. A lower surface of the sealing material 72 and the lower surface of the first eyelet 51 lie on a single plane, for example.

Each of the leads 61 through 66 protrudes upward from the upper surface of the eyelet 50. Each of the leads 61 through 66 protrudes downward from the lower surface of the eyelet 50. Amounts of lead protrusion from the upper surface and the lower surface of the eyelet 50 may be the same as in the first embodiment, for example. The material used for the leads 61 through 66 may be the same as that used for the leads 21 through 24, for example.

A portion of the lead 61 protruding upward from the upper surface of the eyelet 50 is electrically connected to the signal pattern of the substrate 80 via a conductive bonding material 90, such as a metal brazing alloy (for example, a gold-tin alloy) or the like. The lead 61 serves as a path which is electrically connected to a light emitting element and through which a signal passes when the light emitting element is mounted on the header 2 and used as the semiconductor package. The leads 62 through 66 serve as a path which is electrically connected to a power supply, and a device, a sensor, or the like mounted on the header 2 and through which the signal passes. The device, the sensor, or the like mounted on the header 2 is a Peltier device or a temperature sensor, for example. The number of leads 61 through 66 is not particularly limited, and may be increased or decreased as necessary.

The wire diameter of the leads 61 through 66 is approximately 0.2 mm or greater and approximately 0.6 mm or less, for example. As described above, the lead 61 serves as the path which is electrically connected to the light emitting element and through which the signal passes when the light emitting element is mounted on the header 2 and used as the semiconductor package. For this reason, the lead 61 preferably has a wire diameter that is as small as possible to increase the impedance. When a strength and the impedance are taken into consideration, the wire diameter of the lead 61 is preferably 0.2 mm or greater and 0.25 mm or less.

On the other hand, the wire diameter of the leads 62 through 66 used for the power supply or the like is preferably made large to a certain extent to reduce the impedance. Specifically, the wire diameter of the leads 62 through 66 is preferably 0.3 mm or greater and 0.6 mm or less when the product size is also taken into consideration. As described above, in the header 2, the wire diameter of the lead 61 serving as the path which is electrically connected to the light emitting element and through which the signal passes when the light emitting element is mounted on the header 2 and used as the semiconductor package is preferably smaller than the wire diameter of the other leads 62 through 66 used for the power supply or the like.

The sealing materials 71 and 72 may be made of an insulating material that is the same as that of the sealing materials 31 and 32. The dielectric constant in the periphery of the lead 61 inside the through hole 52x may be other than air as long as the dielectric constant is smaller than the dielectric constant of the sealing material 71. For example, a resin material having a lower dielectric constant than the sealing material 71 may be disposed in the periphery of the lead 61 inside the through hole 52x. In this case, the lead 61 can be more firmly fixed with respect to the eyelet 50.

The header 2 can also achieve the same effects as the header 1 described above.

### Modification of Second Embodiment

In a modification of the second embodiment, an example of the header for the semiconductor package having an eyelet with a shape different from that of the second embodiment will be described. In the modification of the second embodiment, a description of the same components or constituent elements as those of the second embodiment described above may be omitted.

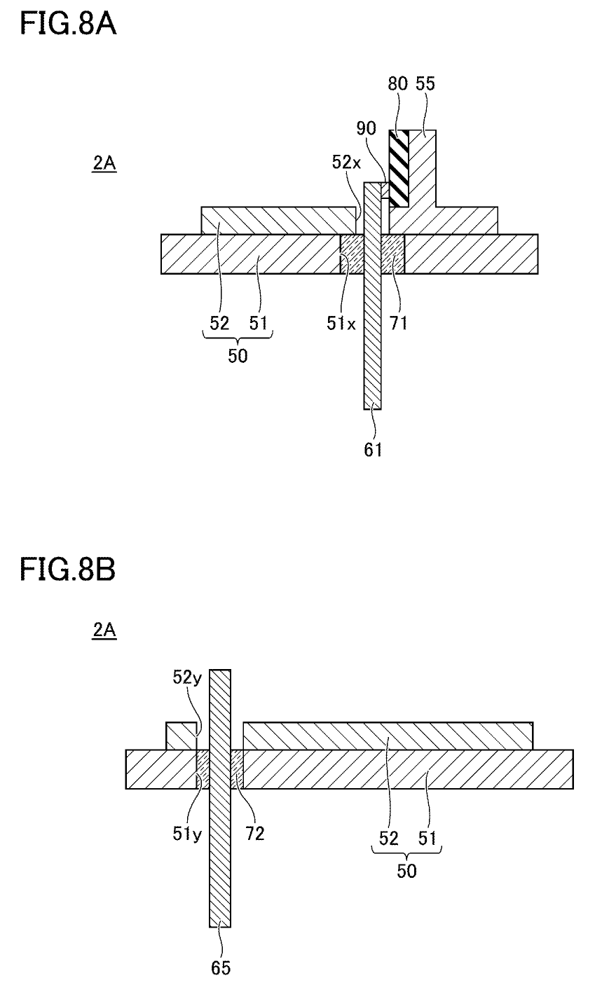

FIG. 8A and FIG. 8B are cross sectional views illustrating an example of the header for the semiconductor package according to a first modification of the second embodiment. FIG. 8A and FIG. 8B illustrate cross sections corresponding to FIG. 7A and FIG. 7B, respectively. A header 2A illustrated in FIG. 8A and FIG. 8B differs from the header 2 in that the second eyelet 52 is smaller than the first eyelet 51 in the plan view.

In the header 2A, the first eyelet 51 is exposed in an annular shape on the outer periphery of the second eyelet 52 in the plan view. For example, a planar shape of the first eyelet 51 is a circular shape, a planar shape of the second eyelet 52 is a circular shape with a diameter smaller than that of the first eyelet 51, and the first and second eyelets 51 and 52 are disposed concentrically.

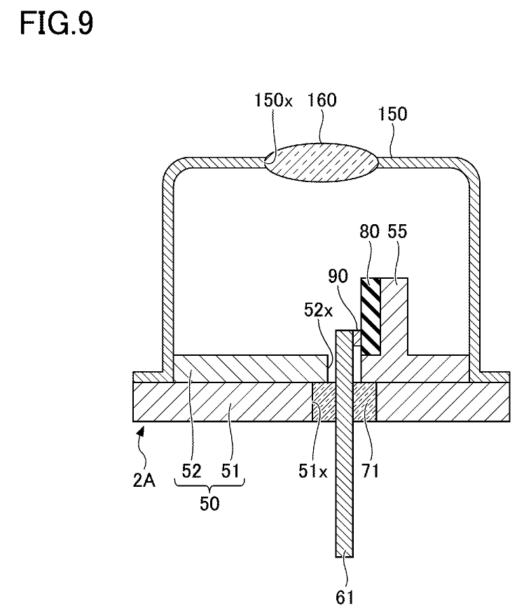

Accordingly, by adopting a structure in which the first eyelet 51 is exposed in the annular shape on the outer periphery of the second eyelet 52 in the plan view, it is easy to attach a cap to the eyelet 50. Hereinafter, a description will be made with reference to FIG. 9.

FIG. 9 is a cross sectional view illustrating a state where the cap is attached to the header for the semiconductor package according to the modification of the second embodiment. As illustrated in FIG. 9, the header 2A can be used by mounting a semiconductor device or the like on the eyelet 50 and then bonding the cap 150 similar to that illustrated in FIG. 3 to the eyelet 50 by resistance welding or the like. Thus, the eyelet 50 and the cap 150 having the transparent member 160 fixed thereon can form an air-tightly sealed space.

Although preferred embodiments are described above in detail, the present disclosure is not limited to the described embodiments, and various modifications and substitutions can be made to the embodiments described above without departing from the scope of the present disclosure. For example, the header 2 or 2A may have a concavo-convex structure such that the first eyelet 51 and the second eyelet 52 are fitted to each other, similar to the header 1A or 1B.

According to the disclosed technique, it is possible to provide a header for a semiconductor package capable of reducing a thickness variation of a sealing material that seals a lead.

Although the embodiments and modifications are numbered with, for example, “first,” or “second,” the ordinal numbers do not imply priorities of the embodiments and modifications. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A header for a semiconductor package, comprising:
a first eyelet provided with a first through hole;
a second eyelet bonded on the first eyelet and provided with a second through hole communicating with the first through hole;
a first lead inserted into the first through hole and the second through hole; and
a first sealing material that seals the first lead inside the first through hole, wherein:
an opening area of the second through hole is smaller than an opening area of the first through hole in a plan view, and
a dielectric constant in a periphery of the first lead inside the second through hole is smaller than a dielectric constant of the first sealing material.

2. The header for the semiconductor package as claimed in claim 1, wherein:
an upper surface of the first sealing material and an upper surface of the first eyelet lie on a single plane, and
a lower surface of the first sealing material and a lower surface of the first eyelet lie on a single plane.

3. The header for the semiconductor package as claimed in claim 1, wherein:
a protrusion protruding with respect to an upper surface of the first sealing material is provided on an upper surface of the first eyelet, and
the protrusion fits into a recess provided in a lower surface of the second eyelet.

4. The header for the semiconductor package as claimed in claim 1, wherein:
a recess that is recessed with respect to an upper surface of the first sealing material is provided on an upper surface of the first eyelet, and
the recess is fitted over a protrusion provided on a lower surface of the second eyelet.

5. The header for the semiconductor package as claimed in claim 1, wherein the first eyelet includes a main body, and a flange protruding outward in an annular shape in a plan view from a lower end of a side surface of the main body.

6. The header for the semiconductor package as claimed in claim 1, wherein the first eyelet is exposed in an annular shape on an outer periphery of the second eyelet in a plan view.

7. The header for the semiconductor package as claimed in claim 1, further comprising:
a third through hole provided in the first eyelet;
a fourth through hole provided in the second eyelet and communicating with the third through hole;
a second lead inserted into the third through hole and the fourth through hole; and
a second sealing material sealing the second lead inside the third through hole,
wherein an opening area of the fourth through hole is equal to an opening area of the third through hole in a plan view.

8. The header for the semiconductor package as claimed in claim 7, wherein the first lead has a wire diameter smaller than a wire diameter of the second lead.

9. The header for the semiconductor package as claimed in claim 1, wherein the first lead is surrounded by air inside the second through hole.

10. The header for the semiconductor package as claimed in claim 1, wherein the first sealing material is glass having a dielectric constant that is 4 or greater and 7 or less and a loss tangent tanδ that is 5 × 10⁻⁴ or less.
